(19) United States
(12) Patent Application Publication
(10) Pub. No.: US 2007/0049069 A1
(43) Pub. Date: Mar. 1, 2007

(54) Location and Means for Connecting to Existing Automotive Electrical Circuits

(76) Inventor: Frank J. Perhats SR., Lake Barrington, IL (US)

Correspondence Address: COOK, ALEX, MCFARRON, MANZO, CUMMINGS & MEHLER LTD, SUITE 2850, 200 WEST ADAMS STREET, CHICAGO, IL, 60606, US

(21) Appl. No.: 11/469,221

(22) Filed: Aug. 31, 2006

Related U.S. Application Data
(60) Provisional application No. 60/713,033, filed on Aug. 31, 2005.

(51) Int. Cl. H05K 1/00

(52) U.S. Cl. 439/76.2

(57) ABSTRACT

An electrical connector is provided for use in a first electrical circuit having a power supply, a load, and a fuse or circuit breaker receptacle. The receptacle has first and second terminals which are spaced apart from one another. The connector has first and second blades made of electrically conductive material. A non-conductive carrier is fixed to the first and second blades. The carrier fixes the blades at a spacing that matches the spacing of the terminals of the one of a fuse or circuit breaker receptacle. The connector can be inserted into the receptacle to provide an electrical connection point for a second electrical circuit.

### CROSS-REFERENCES TO RELATED APPLICATIONS

This application claims the benefit of U.S. Provisional Application 60/713,033, filed Aug. 31, 2005.

### BACKGROUND OF THE INVENTION

This invention relates to electrical connections for automotive aftermarket products such as burglar alarms, remote starter systems and, particularly in the instance of the present invention, a no idle interior heating system. No idle interior heating systems, also known as after-run heating systems, are shown and described in U.S. Pat. Nos. 6,116,513 and 6,926,207, the disclosures of which are incorporated herein by reference. When electrically operated automotive aftermarket products are installed, a connection to a specific, existing vehicle electrical circuit must frequently be made. This connection is required either to supply power or to gain control of a circuit component. The power is supplied or the control function acquired, in parallel with the existing supply from another controlling source or, as in the case of a no idle heating system, during a time when the ignition is off and the circuit is normally unpowered. U.S. Pat. No. 6,848,915 shows one type of connector related to the present invention.

Locating, identifying and connecting to such circuits in modern vehicle harness systems can be very difficult and time consuming and in many situations it is almost impossible. The task is fraught with the dangers of misidentification that can result in damage or destruction of costly components. An example of this is attempting to connect battery plus at a control element such as a switch or fan speed control switch. The connection is complicated by the need to identify whether the circuit control element is located on the supply side or ground side of the load. Attempting to supply battery plus, for example to the input side of a switch or control element that is located in the circuit on the ground side of the load, can have disastrous consequences.

To diminish the described installation complexities and uncertainties, alternative connection means must be addressed in the installation instructions and the additional connection hardware must be included with the product so as to accommodate as broad a range of vehicle types and models as possible. This still leaves much of the installation decisions in the hands of the installer without any significant reduction in the possibility of installation errors. An alternative is to generate model specific products which can increase product cost and complicate distribution, both of which increase product cost and diminish product acceptance in the marketplace.

Further, although connectors exist for tapping (obtaining power) for installation of new circuits at the fuse, these products are designed to connect to the supply side of the fuse only. Or, these devices may be of the loose terminal type designed to be clipped to the engagement blade of the fuse when the two are reinserted into the fuse receptacle. In many instances, the added thickness of the two blades exceeds the thickness accepted by the fuse receptacle and simply cannot be used. Even if the blades are successfully reinserted, they are very unstable by the nature of their design and likely to move when wires are connected to them. The movement can cause the connection to be lost or to short across the fuse resulting in the loss of fuse protection for the circuit. These devices are makeshift, designed for do-it yourselfers, and not reliable enough for commercial use.

Therefore, the task of making a connection to both the supply side and load side of a fuse, for the purpose of gaining parallel control of a given circuit at the circuit's fuse location, necessitates the use of a more reliable connection means than those currently available. An object of this invention is to provide a reliable connection device that can only be used at the readily available fuse location that protects the intended circuit.

This invention then proposes both a specific connection point, universally available on virtually all vehicles and vehicle circuits, coupled with a unique and simple device with which to accomplish the connection and further proposes integrating a fusible element within the connection device to protect a load from excessive current.

### SUMMARY OF THE INVENTION

The present invention proposes that connections to vehicle electrical systems be made at the fuse or circuit breaker protecting the circuit that is being connected to and proposes a simple and unique means by which to make such a connection.

A fuse can be described as a fusible conductive element having two terminals to connect the fusible element in series between the circuit power supply and the circuit load. The connecting means of this invention proposes a device that emulates in size, configuration and location the connecting terminals specific to various sizes and types of fuses currently in use but without a fusible element between them. The blades of the connecting device are held apart by a non-conductive support a distance appropriate to fit the device in place of the removed fuse, with said insertion portion of each blade having on its opposite end, a means for the connection of electrical wires. By the nature of the product, this invention proposes inserting the above described device in place of the circuit protecting fuse located at the circuit being connected to. Said device, when installed in place of the fuse, permits electrical connections to be made for the purpose of powering or controlling the supply side, the load side, or both sides or reconnecting the circuit to its original configuration.

Additional embodiments integrate a fuse or fusible element within the fuse connector. These embodiments are especially useful to original equipment manufacturers (OEMs) that desire to provide a specific and handy connection point for the installation of aftermarket or optional accessories.

The invention anticipates adaptation of the concept to fit any old or new configuration of fuse design including connection at circuits protected by circuit breakers.

### BRIEF DESCRIPTION OF THE DRAWINGS

FIG. 1 is a front elevation view of a connection device designed for use in connecting to circuits protected by a MAXI fuse.

FIG. 2 is a front elevation view of a connection device designed for use in connecting to circuits protected by an ATO/ATA fuse.

FIG. 3 is a front elevation view of a connection device designed for use in connecting to circuits protected by a mini fuse now frequently used in passenger cars and newer trucks.

FIG. 3A is a side elevation view of the connection device of FIG. 3.

FIG. 4 is a front elevation view of an alternate embodiment of a connector that is designed to connect to what is now rarely used in automotive applications, a glass tube type fuse, and illustrates the adaptability of the concept to any fuse design.

FIG. 4A is a side elevation view of the connection device of FIG. 4.

FIG. 5 is a circuit diagram of a control element, in the form of a switch, located in the circuit on the supply side of the load.

FIG. 6 is a circuit diagram of a control element, in the form of a switch, located in the circuit on the ground side of the load.

FIG. 7 is a circuit diagram showing the use of the device of the present invention inserted in a fuse location and illustrating the device's use in connecting to and controlling both the supply side and load side of the circuit.

FIG. 8 is a front elevation view of the standard MAXI fuse connector of FIG. 2 which includes a fusible element disposed between the first and second blades of the fuse connector.

FIG. 9 is a front elevation view of another embodiment of FIG. 8 with a fusible element in series with auxiliary load connection terminal and another fusible element protecting the in-vehicle load.

FIG. 10 illustrates yet another embodiment of FIG. 8 in which a male quick connect terminal is absent from one of the fuse engagement blades.

FIG. 11 illustrates a further embodiment of the fuse connector utilizing a shorting bar.

### DETAILED DESCRIPTION OF THE INVENTION

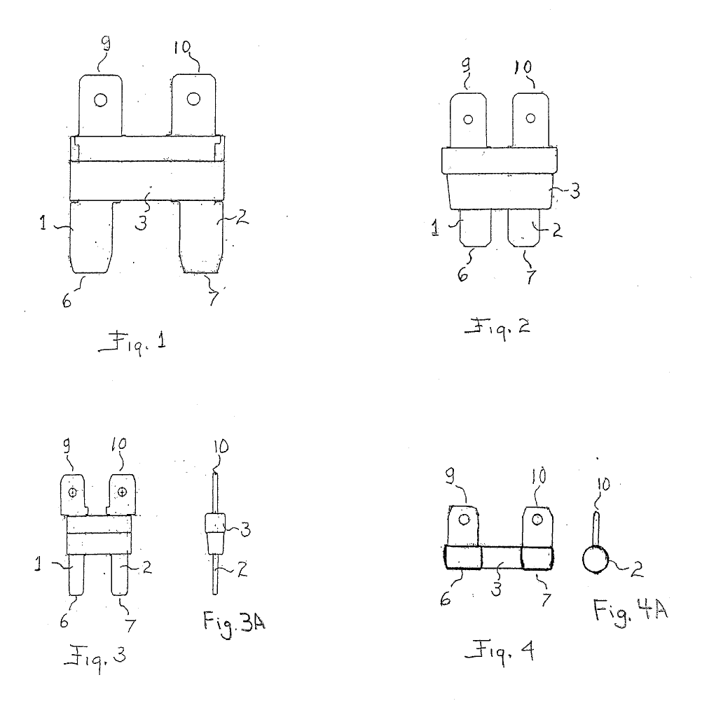

FIGS. 1, 2, 3 and 3A illustrate the commonality of design concept between the various sizes (types) of fuses while FIGS. 4 and 4A illustrate the adaptability of the invention and how it can be configured to fit virtually any design or size of fuse now in existence or proposed.

The fuse connector of the present invention includes first and second electrically conductive blades 1 and 2 which are joined by a non-conductive carrier 3. The blades are mirror images of each other for a specific fuse size or type and are spaced from each other by the non-conducting carrier 3. The carrier 3 is affixed to the blades 1 and 2 by means deemed acceptable in manufacturing such as insert molding, forced insertion, riveting, cementing, heat, friction or ultrasonic welding case halves or any other high speed, low cost production means appropriate to a specific design.

Each blade pair 1 and 2 has a fuse receptacle engagement portion 6 and 7. On the end opposite of the blades there are male quick connect terminals 9 and 10. These are designed to accept equivalently sized, standard, insulated female quick connect terminals commonly used and available in the wiring industry to make wire conductor connections. The invention anticipates the use of many other means of wire connection such as but not limited to, soldering, welding, crimping, or any other means of connection which now exists or may become available in the future.

FIGS. 4 and 4A illustrates the adaptability of the concepts embodied in the invention incorporating the same functional elements in a glass AGC type fuse as are incorporated in the fuses of FIGS. 1, 2 and 3.

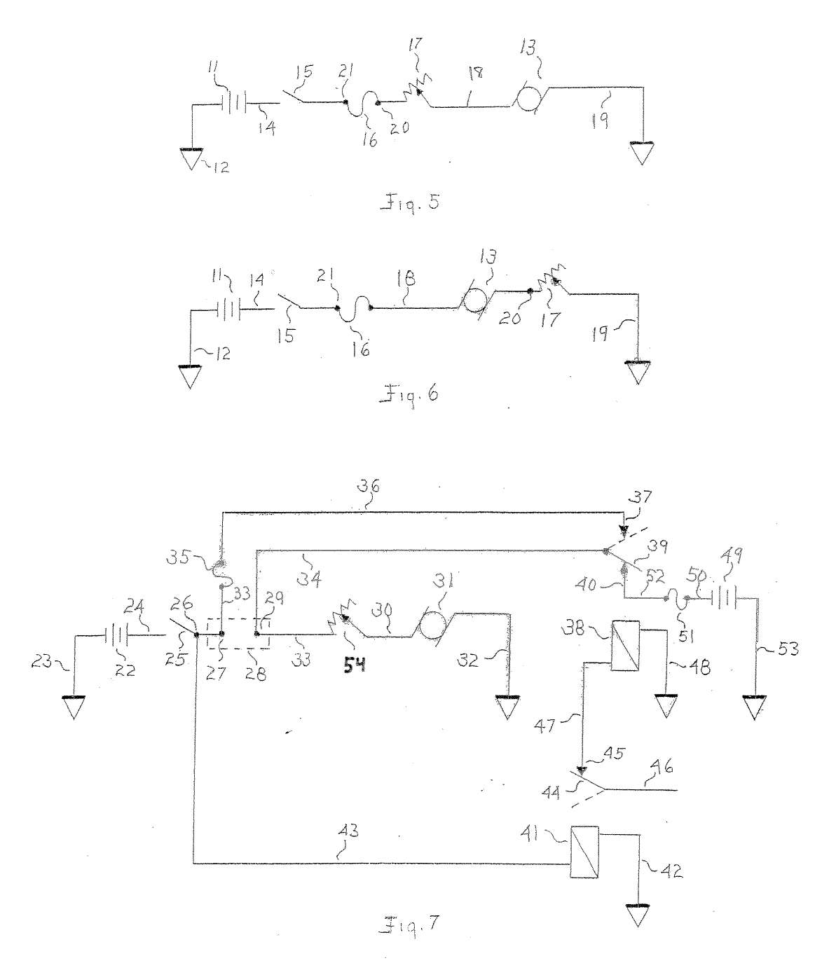

FIGS. 5 and 6 illustrate the difficulty in connecting secondary, parallel power and control circuits at the vehicle's existing circuit control element, i.e., switches, fan speed controls or the like. A battery 11, grounded at 12 provides battery plus to fan motor 13 by way of conductor 14, ignition switch 15, fuse 16, motor speed control switch 17 and conductor 18. Fan motor 13 is connected to battery ground by way of conductor 19. Connecting battery plus at 20 when ignition switch 15 is open, powers the circuit with the ignition off and provides full control of the fan speed via fan speed control switch 17.

In FIG. 6 battery 11, grounded at 12, provides battery plus via conductor 14, ignition switch 15, fuse 16 and conductor 18 to the fan motor 13. Fan motor 13 is connected on its ground side to fan speed control switch 17, which then provides return to battery ground via conductor 19. Applying battery plus power at 20 of speed control switch 17, as would be commonly done when connecting to such heater fan circuits, would have disastrous consequences because it is applied on the ground side of the load. As can be seen in FIGS. 5 and 6, applying battery plus at the supply side 21 of fuse 16 supplies battery power to either circuit and eliminates the need to give prior consideration to the location in the circuit of the control element 17 with respect to the load 13. As can be seen from the above, connecting to either circuit at the universally available fuse location and with the connection device of the present invention is both fast and secure and eliminates the need to give consideration to this circuit variant between vehicle models.

FIG. 7 illustrates part of a circuit schematic for an aftermarket, no idle vehicle interior heating system connected to a vehicle's heater fan which illustrates the devices ability to quickly make connection to the supply and load side of a vehicle's fan control circuit for the purpose of operating and terminating fan operation (gain parallel control) with the ignition off. With the fuse present across fuse receptacles 27, 29, fan motor 31 is supplied power from battery 22 via conductor 24, closed ignition switch 25, conductor 26 to the supply side 27 of fuse receptacle, across the fuse to receptacle 29, conductor 33, fan speed control switch 54, conductor 30 and to fan motor 31, powering the fan by way of ground conductor 32. Removing the fuse from receptacles 27 and 29 and replacing it with the fuse connection device 28, facilitates the connection of external wires 33 and 34 which are part of the no idle heating system. This makes it possible to power and control the fan through the no idle heating system with the ignition off.

With conductors 33, 34 now connected respectively to fuse receptacles 27, 29, control of the fan circuit is transferred to the no idle heating system as follows. Ignition relay 41, grounded at 42 is part of the no idle system and responds to the position of the ignition switch being powered via conductor 43 when the ignition is switch 25 is closed and dormant when the ignition switch 25 is open and the ignition is off. When the ignition switch 25 is closed, the ignition is on, and the vehicle is running, ignition relay 41 is powered via conductor 43. Its transfer contact 44, being disengaged from back contact 45, interrupts battery power supplied through the no idle system by way of conductor 46. Fan relay 38, also a part of the no idle system, is now dormant. When relay 38 is dormant, transfer contact 39 becomes engaged with relay 38 back contact 37 effectively returning the fan 31 power supply to the original source as follows. Battery plus flows from battery 22 via conductor 24, closed ignition switch 25, conductor 26 to fuse connection device 28 contact now engaged with receptacle 27, to conductor 33, fuse 35, conductor 36 to dormant fan relay 38 back contact 37 engaged with dormant fan relay 38 transfer contact 39, to conductor 34, to fuse connector device 28 power side terminal now engaged with fuse receptacle 29. This transfers battery via conductor 33, fan speed control switch 54, and conductor 30 to heater fan motor 31, thereby supplying fan power from the original source when the ignition is on and the engine running.

With the ignition switch 25 open, ignition relay 41 is dormant causing transfer contacts 44 to transfer battery power from the no idle heating system via conductor 46, contact 45 connected to conductor 47 thereby powering relay 38. Powering fan relay 38 causes transfer contact 39 to engage contact 40 connected internally within the no idle system to battery 49 via conductor 52, fuse 51, conductor 50 to battery 49, which is grounded via conductor 53. Thus power from battery 49 is transferred from contact 40 engaged with contact 39 to conductor 34, fuse connector 28, load side contact 29, conductor 33, fan speed control switch 54, conductor 30, to heater fan motor 31 grounded via conductor 32, thereby causing heater fan 31 to operate with full control of speed and other functions with the ignition off.

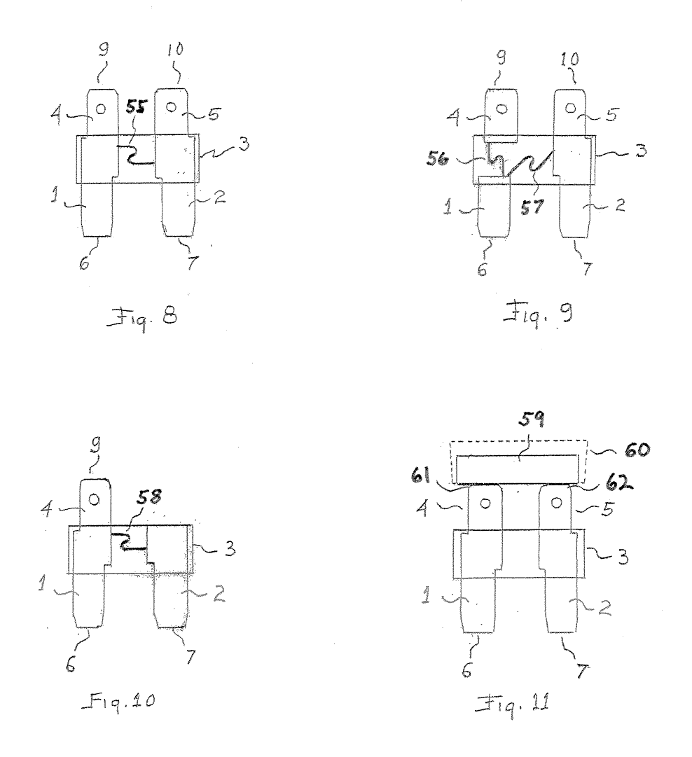

In additional embodiments of the fuse connector, the fuse connector incorporates additional fusible elements between the first and second conductive blades, as illustrated by the drawings of FIGS. 8, 9 and 10, for example. Similar elements that are common to the different embodiments are identified by common numbers as demonstrated as FIGS. 8-11. The combination of connection means proposed in the above embodiments and those proposed herein, are similar except for the addition of fusible elements interposed between their connecting means. The configuration of the embodiment shown in FIG. 8 is similar to the configuration of the fuse connectors shown in FIGS. 1-3, except for the inclusion of a fusible element 55 between the first and second electrically conductive blades 1 and 2. The fusible element 55 or fuse element 55 acts as a normal fuse or the typical fuse which the fuse connector replaces as a result of its installation into a fuse box or fuse receptacle.

For example, if the first blade 1 of the fuse connector shown in FIG. 8 is connected to the supply side of a fuse receptacle or fuse box (not shown), then the in-vehicle load (not shown), which would be connected to the second blade 2, would be protected from excessive electrical currents by fusible element 55. It should be noted that the aftermarket accessories, additional devices, or loads connected to the male quick connect terminal 9 of the first blade 1 would not be protected by fusible element 55 because the fuse element is not in series with quick connect terminal 9 or with the aftermarket accessory or additional loads connected to terminal 9. On the other hand, additional loads, devices, or aftermarket accessories attached at the quick connect terminal 10 located on the second blade 2 would be protected by the fusible element 55, which also protects the in vehicle load connected at the receptacle engagement portion 7 of the second blade 2.

FIG. 9 illustrates an embodiment which incorporates two fusible elements. In this embodiment, the fusible element 56 is located between the first electrically conductive blade 1 and the accessory connection terminal 4. A second fusible element 57 is located between first blade 1 and the second blade 2, which could be connected to the in-vehicle load. In this embodiment, both the in-vehicle load and accessory loads connected to the terminals 4 or 5 are protected by fusible elements 56 or 57. The fuse values of fuse elements 56 and 57 could differ and, as a result, could meet different protection needs. As a result from using two fusible elements in the configuration shown in FIG. 9, the in-vehicle load connected to receptacle-blade 2 in FIG. 9 would not be affected by the opening of fusible element 56 caused by overloading the load connected at accessory-blade 4. In FIG. 8, an accessory overload connected at terminal 5 would open fusible element 55 and disconnect the in-vehicle load connected to the second blade 2 since connection terminal 5 and the load connecting to the second blade 2 share the protective fuse element 55.

Another embodiment is illustrated by FIG. 10 where quick connect terminal 5 is eliminated, which prevents the sharing of the fuse element 58 by an accessory load. The embodiment in FIG. 10 may be inserted in to a fuse receptacle or fuse box (not shown) in a reverse manner, that is: the second blade 2 would be connected with the in-vehicle battery supply and the first blade 1 would engage the in-vehicle load.

FIG. 11 shows another embodiment of the fuse connector proposed in FIGS. 1, 2, 3 and 4. This embodiment is intended for use by original equipment manufacturers as a low cost and readily available connection point to in-vehicle systems when parallel connection and control of the in-vehicle system is required. For example, the fuse connector shown in FIG. 11 may be utilized as the fuse connector 28 as demonstrated in FIG. 7. Typically, the fuse connector shown in FIG. 11 would be inserted in an unused fuse location, in series with the fuse but between the fuse and the load intended for connection.

The fuse connector of FIG. 11 includes first and second electrically conductive blades 1 and 2 which are joined by a non-conductive carrier 3. The blades are mirror images of each other for a specific fuse size or type and are spaced from each other by the non-conducting carrier 3. Each blade pair 1 and 2 has a fuse receptacle engagement portion 6 and 7. On the end opposite of the blades there are terminals 4 and 5. Connecting terminals 4 and 5 is a shorting bar 59 which electrically connects the first blade 1 and the second blade 2. Shorting bar 59 is insulated with non-conductive insulation cover 60 which prevents accidental contact with the shorting bar 59. Between the shorting bar 59 and terminals 4 and 5 are score marks 61 and 62. These score marks designate the separation point between the terminals 4 and 5 and the shorting bar 59. Shorting bar 59 may be separated and removed from terminals 4 and 5 by physically breaking the connections at score marks 61 and 62. As result of breaking the connection and removing the shorting bar 59, terminals 4 and 5 are exposed for connection thereto as previously described for FIGS. 1, 2, 3, 4, 8, and 9.

The fuse connector shown in FIG. 11 is especially beneficial for original equipment manufactures (OEMs) that intend to make connections to aftermarket accessories, devices, or systems. For example, the fuse connector of FIG. 11 may be inserted into an in-vehicle fuse receptacle or fuse box (not shown), wherein the second blade 2 is connected to the load side of the fuse designated for protection of the in-vehicle system. The first blade 1 of the fuse connector is therefore connected to and supplies power to this in-vehicle system. Current flowing from the in-series fuse enters the first blade 1, flows through terminal 4, then to terminal 5 via shorting bar 59, and from terminal 5 to the second blade 2. Insulation cover 60 minimizes accidental contact with shorting bar 59 and may extend down to encompass and cover part or all of connection terminals 4 and 5. In this example, the fuse connector as shown in FIG. 11 acts only as an electrical current conductor in series with the fuse (not shown) and the load (not shown). It cannot perform the dual functions described by the devices of FIGS. 8, 9, and 10 because it does not incorporate a fusible element. If the fuse connector of FIG. 11 contained a fusible element disposed between the first and second blades 1 and 2 as shown FIGS. 8, 9, and 10, then the electrical current would bypass or short the fusible element via the shorting bar 59.

To make a connection between an in-vehicle system connected the fuse connector of FIG. 11 and an after market accessory, such as a no-idle heating system, shorting bar 59 must be removed to expose and permit access to connection terminals 4 and 5. The shorting bar 59 may be separated from terminals 4 and 5 at score marks 61 and 62. Score marks 61 and 62 are shallow enough to permit clean and easy removal by bending the shorting bar 59 back and forth at the score marks 61 and 62. However, score marks 61 and 62 are designed not to significantly reduce the current carrying capacity of the interface between the shorting bar 59 and connection terminals 4 and 5. This invention contemplates alternate methods of interconnecting connection-blades 4 and 5 such as quick connect terminals connected to short jumper wires or other more costly systems.

Upon removable of shorting bar 59, connection terminals 4 and 5 are exposed for connection thereto as previously described for FIGS. 1-4, 8, and 9. As a result, the device of FIG. 11 eliminates the need to cut wires in order to gain connection to or secondary control of an existing in-vehicle electrical system.

This invention contemplates other means such as the use of more expensive sockets with removable shorting bars and engaging plugs to accomplish connection to existing in-vehicle electrical systems.

The versatility and benefits of making circuit connections for powering or obtaining parallel control at the fuse/circuit breaker using the fuse connector device of this invention now becomes obvious with the device and the fixed location where its design requires it to be used being inextricably linked as one invention. The design innovations proposed by this invention are not intended to be limited to the configurations described herein and are versatile enough to be incorporated into any fuse/circuit breaker design of the past or any future design. Nor is it intended to be limited in use solely for use in connecting to vehicle heater fans or for use only in no idle heating systems, which are referred to herein for illustration purposes only.

The versatility of the connection point and connection means of this invention to accomplish vehicle electrical connections at the fuse /circuit breaker location are inseparably linked in concept and function and applicable to the installation of any automotive electrical device connected to any vehicle electrical circuit.

I claim:

1. In an electrical circuit of the type having a power supply, a load, and at least one of a fuse or circuit breaker receptacle having first and second terminals which are spaced apart from one another, the improvement comprising a connector for making electrical connection to the fuse or circuit-breaker receptacle, the connector comprising:
first and second blades made of electrically conductive material; and
a non-conductive carrier fixed to at least a portion of the first blade and at least a portion of the second blade, the carrier fixing the first and second blades such that at least a portion of the first blade and a portion of the second blade have a spacing that matches the spacing of the terminals of the one of a fuse or circuit breaker receptacle.

2. The connector of claim 1 wherein the first blade is physically separated and electrically isolated from the second blade.

3. The connector of claim 1 wherein each of the blades includes a receptacle engagement portion.

4. The connector of claim 3 wherein each of the blades includes a connection terminal, the connection terminal being located on a side of the blade opposite the receptacle engagement portion.

5. The connector of claim 4 wherein the connection terminal is a male quick connection terminal.

6. The connector of claim 5 wherein the blades are arranged such that they are mirror images of each other.

7. The connector of claim 1 wherein the non-conductive carrier encircles at least a portion of the first blade and at least portion of the second blade.

8. The connector of claim 1 wherein the non-conductive carrier is fixed to the first and second blades by an attachment method selected from the group consisting of: insert molding, forced insertion, riveting, cementing, heat sealing, friction fitting, friction sealing, or ultrasonic welding.

9. The connector of claim 1 wherein the non-conductive carrier spaces the first and second blades a distance such that the entirety of the blades have a spacing that matches the spacing of the terminals of the one of a fuse or circuit breaker receptacle.

10. The connector of claim 1 wherein the non-conductive carrier is fixed to the first and second blades by a rivet.

11. The connector of claim 1 further comprising a shorting bar, the shorting bar being removably coupled to and in electrical communication with the first and second blades.

12. The connector of claim 1 further comprising a fusible element, the fusible element being in electrical communication with the first blade.

13. The connector of claim 12 wherein the fusible element is disposed within the non-conductive carrier.

14. The connector of claim 12 wherein the fusible element is electrical communication with the second blade.

15. The connector of claim 12 further comprising a connection terminal, the connection terminal being made from a conductive material, the connection terminal being affixed to the non-conductive carrier.

16. The connector of claim 15 further wherein the connection terminal is in electrical communication with the fusible element.

17. The connector of claim 12 further comprising a second fusible element.

18. The connector of claim 17 wherein the second fusible element is in electrical communication with the first blade.

19. The connector of claim 18 further comprising a connection terminal, the connection terminal being made from a conductive material, the connection terminal being affixed to the non-conductive carrier, wherein the connection terminal is electrical communication with the fusible element, and the second blade is in electrical communication with the second fusible element.

20. A circuit for controlling a load, comprising:
at least one power source, an ignition switch and a fuse receptacle all connected in series;
a fuse connector in electrical engagement with the fuse receptacle and having first and second terminals;
a switching means for selecting a circuit pathway in response to the position of the ignition switch, the switching means electrically connected between the first terminal and the second terminal of the fuse connector device; and
a load, the second terminal being electrically connected to the load.

21. The circuit of claim 20 wherein the ignition switch is electrically connected to said at least one power source.

22. The circuit of claim 21 wherein the fuse receptacle is electrically connected to the ignition switch.

23. The circuit of claim 22 where in the first terminal is electrically connected to the ignition switch by way the fuse receptacle.

24. The circuit of claim 20 wherein a second power source is electrically connected to the switching means, whereby the second power source provides a power supply to the second terminal when the ignition switch is open.

25. The circuit of claim 20 wherein the load is a fan.

26. The circuit of claim 25 further comprising:
a fan speed control switch and the fan speed control switch being connected between the second terminal and the fan.

27. The circuit of claim 20 further comprising:
a first fuse, the first fuse connected between the first terminal and the switching means.

28. The circuit of claim 24 further comprising:
a first fuse, the first fuse connected between the first terminal and the switching means; and
a second fuse, the second fuse connected between the second power source and the second terminal.

29. The circuit of claim 20 wherein the switching means comprises:
an electrical relay connected to the ignition switch, the relay being activated when the ignition switch is closed, whereby the electrical relay activates the switching means.

30. The circuit of claim 24 further comprising:
a first circuit pathway from the first terminal to the switching means and connecting to the second terminal; and
a second circuit pathway from the second power source to the switching means and connecting to the second terminal,
wherein the switching means selects as the circuit pathway either the first circuit pathway or the second circuit pathway.

31. The circuit of claim 20 wherein the circuit pathway comprises electrical connections from the first terminal to the second terminal, wherein the switching means electrically connects the first terminal to the second terminal when the ignition switch is closed.

32. The circuit of claim 24 wherein the circuit pathway comprises electrical connections from the second power source to the second terminal, wherein the switching means electrically connects the second power source to the second terminal when the ignition switch is open.
